(19) United States
(12) Patent Application Publication
(10) Pub. No.: US 2011/0154811 A1
(43) Pub. Date: Jun. 30, 2011

(54) Device For Generating Electrical Energy, Heat Exchange Bundle Comprising Such A Device, And Heat Exchanger Comprising Such A Bundle

(76) Inventor: Michel Simonnin, Voisins-le-bretonneux (FR)

(21) Appl. No.: 13/000,520

(22) PCT Filed: Jun. 22, 2009
(86) PCT No.: PCT/EP2009/057729

§ 371 Date: Mar. 16, 2011

(30) Foreign Application Priority Data
Jun. 24, 2008 (FR) 0803518

(51) Int. Cl. F01N 5/02; H01L 35/30

(52) U.S. Cl. 60/320; 136/205

(57) ABSTRACT

The invention relates to a device for generating electrical energy by conversion of calorific energy into electrical energy, comprising:
a first duct for a hot fluid (5), the hot fluid having a temperature T1;
a second duct for a cold fluid (6), the temperature of which is lower than the temperature T1 of the hot fluid; and
a thermoelectrical element (10, 10′), having at least two faces, arranged to generate an electric current between its faces when they are at different temperatures,
the faces of the thermoelectrical element (10, 10′) being linked respectively to the ducts for fluids of different temperatures (5, 6) via thermal conduction means (15, 16).

The invention relates to the field of thermoelectricity and, more particularly, the conversion of calorific energy (heat) into electrical energy (electricity).

One aim of the invention is to limit the emission of pollutant particulates by a motor vehicle by limiting its energy consumption drawn from the fuel and by using, as a partial substitute, electrical energy generated by thermoelectrical elements.

Thermoelectrical elements are known that have at least two faces, which have the particular feature of generating an electric current between the two faces of the element when the faces are at different temperatures. In other words, if one face of the thermoelectrical element is heated while its other face is cooled, it creates a displacement of electrons between the hot and cold faces of the thermoelectrical element, the displacement of electrons forming an electric current. The greater the difference in temperatures between the faces of the thermoelectrical element, the greater the electrical energy generated by the element. The generation of an electric current by a thermoelectrical element subject to a temperature difference (thermal gradient) is known by the name “Seebeck effect”.

The thermoelectrical elements are used mainly in the production of the wings of space satellites. A satellite wing comprises, conventionally, a first hot face which is turned toward the sun and a second cold face, opposite to the first, which is turned toward the sidereal vacuum. Thus, by arranging a thermoelectrical element between the two faces of a wing of a space satellite, an electric current can be generated to power various electrical equipment items of the satellite.

One of the drawbacks of the thermoelectrical elements lies in the fact that they have a very low efficiency in converting calorific energy into electrical energy, this efficiency being conventionally of the order of 1 to 10%. Therefore, a large quantity of heat must be supplied to the thermoelectrical element to generate an electric current that is sufficient to power at least one electrical equipment item.

In order to limit the thermal losses and increase the conversion efficiency, electrical energy generation devices are known in which the faces of a thermoelectrical element, having at least two faces, are directly and respectively in contact with a cold heat source and a hot heat source. When there is direct contact between a heat source (cold or hot) and a face of the thermoelectrical element, the calorific energy originating from the heat source is transmitted with little in the way of thermal losses to the thermoelectrical element. On the other hand, from the electrical point of view, because of the direct contact between the heat source (cold or hot) and the face of the thermoelectrical element, the electrical energy tends to disperse in the heat source without being able to be exploited.

As an example, when the hot and cold heat sources are respectively in the form of hot and cold fluids circulating in metal fluid ducts, electrical leaks appear both in the metal fluid ducts and in the fluids themselves. Because of the electrical losses, the quantity of electrical energy that can be exploited is very low.

The electric current that is created between the two faces of the thermoelectrical element by Seebeck effect is conventionally directed from the electrical energy generation device via electric cables linked to the faces of said thermoelectrical element. However, such cables are complex to connect to the thermoelectrical element when the latter is “sandwiched” (inserted) between two metal fluid ducts. Furthermore, the presence of cables conveying the electric current increases the risk of short circuit within the electrical energy generation device.

In order to eliminate these drawbacks, the invention relates to a device for generating electrical energy by conversion of calorific energy into electrical energy, comprising:
a first duct for a hot fluid, the hot fluid having a temperature T1;
a second duct for a cold fluid, the cold fluid having a temperature T2 which is lower than the temperature T1 of the hot fluid; and
a thermoelectrical element, having at least two faces, arranged to generate an electric current between, its faces when they are at different temperatures,
the faces of the thermoelectrical element being linked respectively to the ducts for fluids of different temperatures via thermal conduction means.

The thermal conduction means of the electrical energy generation device advantageously make it possible to favor the transmission of heat between the thermoelectrical element and the fluid ducts, thus making it possible to supply a large quantity of calorific energy and generate a large quantity of electrical energy by Seebeck effect.

Furthermore, the thermal conduction, means form an intermediary for the electrical conduction between the fluid ducts and the thermoelectrical element, thus limiting the electrical losses from the thermoelectrical element to the fluid ducts and the fluids themselves.

Preferably, the thermal conduction means are arranged to form, with the thermoelectrical element, an electric battery of which said thermal conduction means are the terminals.

Thus, the electrical current generated by the thermoelectrical element can be taken by the thermal conduction means, thus avoiding recourse to additional electrical cables dedicated to conveying the electric current which are bulky and likely to create short circuits.

Preferably, the thermal conduction means are arranged to electrically insulate the fluid ducts of the thermoelectrical element, advantageously making it possible to even more effectively limit the electrical losses in the device.

The thermal conduction means thus advantageously fulfill a dual function (thermal conduction and electrical insulation), which makes it possible to increase the calorific energy conversion efficiency while retaining a compact device.

Also preferably, the thermal conduction means are arranged to ensure that the fluid ducts are kept in position. The thermal conduction means thus provide an additional securing function, which makes it possible to form very compact energy generation devices.

According to a particular embodiment of the invention, the thermal conduction means are in the form of a first hot thermal conduction separator, for example a metal plate, linked to the hot fluid duct, and a second cold thermal conduction separator, for example a metal plate, linked to the cold fluid duct, the hot and cold separators being linked to two different faces of the thermoelectrical element.

Preferably, each separator includes a thermal insulation orifice and a thermal conduction orifice, each fluid duct passing through the two separators.

The invention also relates to a heat exchange bundle of a heat exchanger for a motor vehicle intended to cool a fluid to be cooled, said fluid to be cooled circulating in at least one duct for fluid to be cooled, said fluid to be cooled being cooled by a coolant, of a temperature lower than that of the fluid to be cooled, said coolant circulating in at least one coolant duct, said bundle comprising an electrical energy generation device as described above, the duct for fluid to be cooled forming the hot fluid duct and the coolant duct forming the cold fluid duct.

Integrating an energy generation device in a heat exchange bundle makes it possible to recover the energy from the hot gases from the engine, which is unused, and convert it into electrical energy that can power electrical equipment items of the vehicle.

Incorporating a thermoelectrical element between the fluid circulation ducts (gas and/or liquid) of the heat exchange bundle advantageously makes it possible to generate energy without modifying the arrangement or increasing the volume of the heat exchanger.

Preferably, the bundle comprising a plurality of ducts for fluid to be cooled and a plurality of coolant ducts, in which the ducts for fluid to be cooled are spatially alternated with the coolant ducts.

Also preferably, the plurality of coolant ducts is kept in position by a plurality of cold separators and the plurality of ducts for fluid to be cooled is kept in position by a plurality of hot separators, the cold separators being spatially alternated with the hot separators.

Preferably, the coolant ducts and the ducts for fluid to be cooled are parallel and coplanar and form, with the hot and cold separators, a row of the heat exchange bundle.

Still preferably, thermoelectrical elements are arranged between the cold separators and the hot separators, each thermoelectrical element having a face in contact with a hot separator and another face in contact with a cold separator.

Preferably, thermoelectrical junctions are arranged between two successive cold separators, a thermoelectrical junction comprising two thermoelectrical elements mounted in reverse directions and separated by a hot separator.

The thermoelectrical junctions make it possible to increase the quantity of electrical energy generated without modifying the configuration of the heat exchanger.

According to another feature of the invention, the cold separators are electrically connected in series with one another.

It is thus possible to recover, advantageously, the electric voltage generated by all the thermoelectrical elements of a row of the heat exchange bundle.

Also preferably, the heat exchange bundle comprises a plurality of rows. The coolant ducts and the ducts for fluid to be cooled, which are parallel, coplanar and held by the hot and cold separators, form a row of the heat exchange bundle.

Still preferably, the rows of the heat exchange bundle are electrically connected in series with one another.

It is thus possible to recover, advantageously, the electric voltage generated by all the rows of the heat exchange bundle.

According to an advantageous embodiment, the fluid to be cooled is a flow of exhaust gas from an internal combustion heat engine of the motor vehicle.

This advantageously makes it possible to reduce the heat of the exhaust gases from the vehicle while generating electricity.

The invention also relates to a heat exchanger comprising a heat exchange bundle as described previously.

The invention will be better understood with the aid of the appended drawing in which:

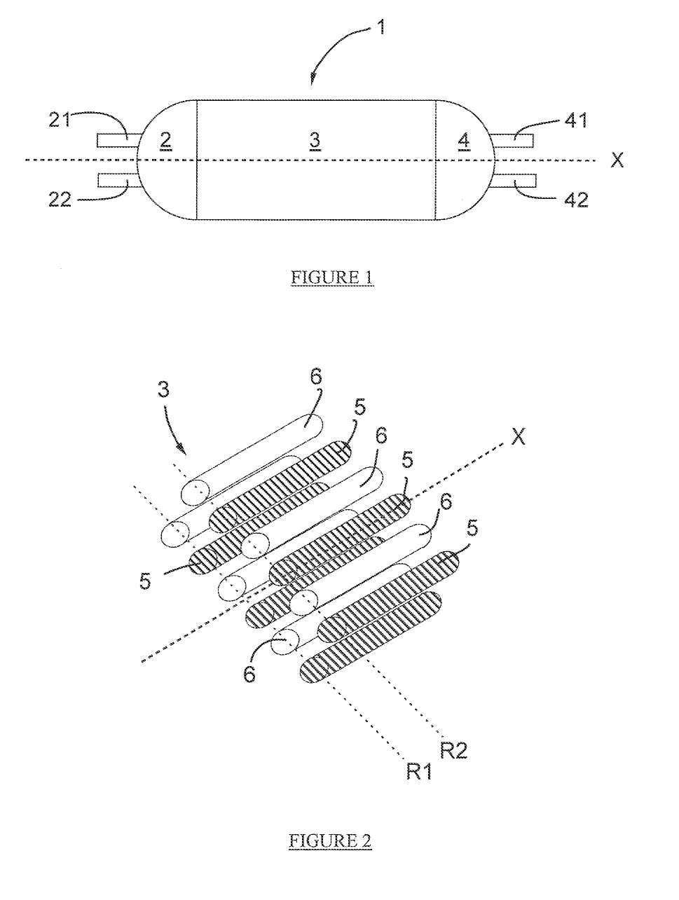

FIG. 1 schematically represents a heat exchanger according to the invention;

FIG. 2 schematically represents a stack of tubes of the heat exchange bundle of the heat exchanger of FIG. 1;

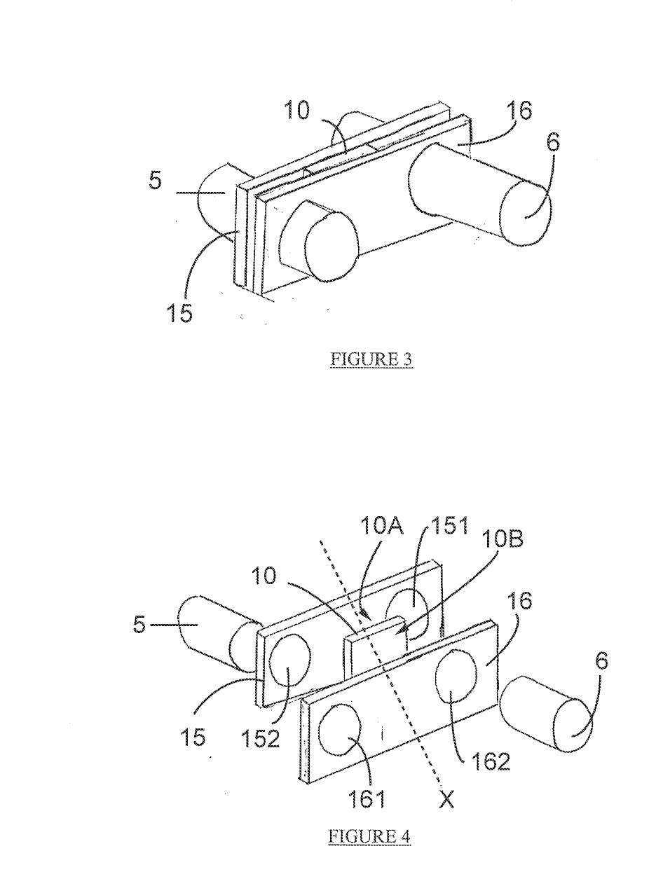

FIG. 3 is a perspective schematic view of the linking of two tubes of a heat exchange bundle with two thermal conduction separators and a thermoelectrical element;

FIG. 4 represents an exploded view of FIG. 3;

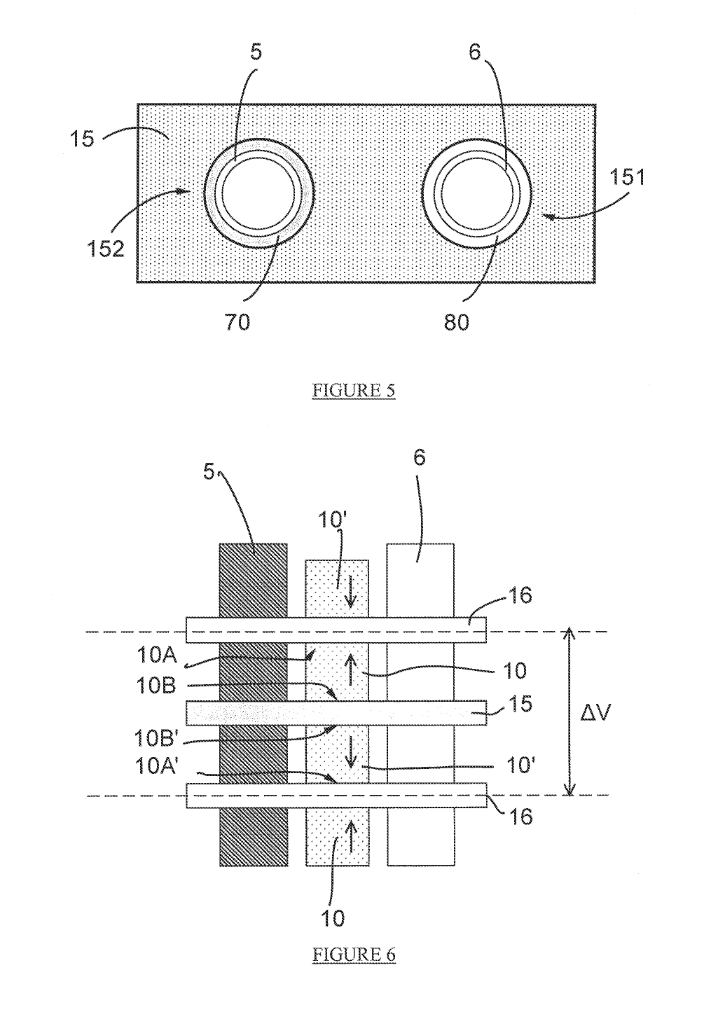

FIG. 5 represents a front view of a separator of FIG. 3;

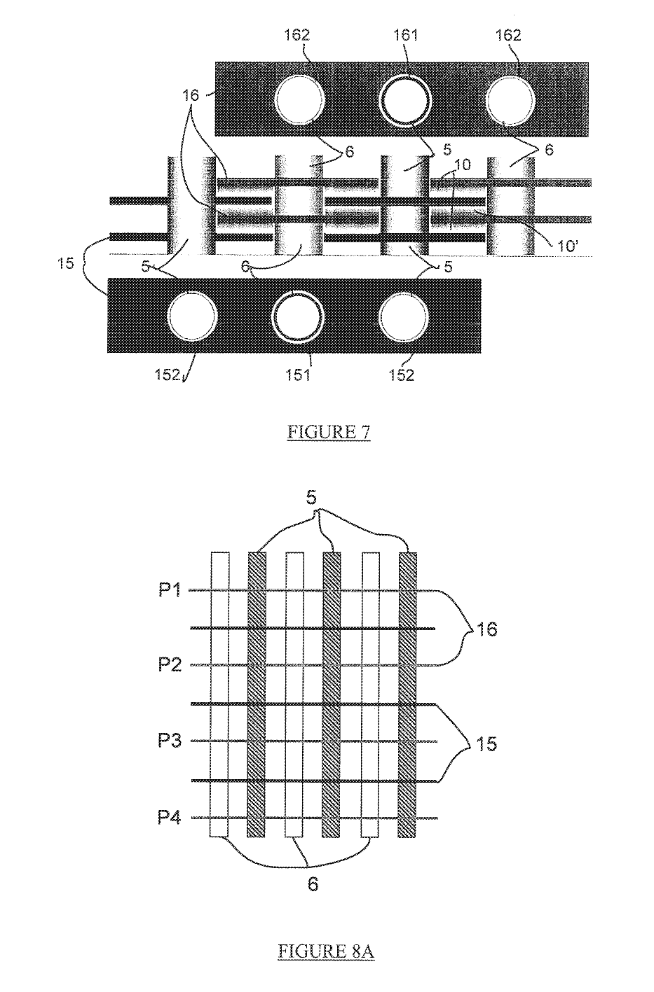

FIG. 6 represents a schematic plan view of the linking of two tubes of a heat exchange bundle with three thermal conduction separators and two thermoelectrical elements;

FIG. 7 represents a schematic plan view of a heat exchange bundle according to the invention, the thermal conduction separators being represented in the front view;

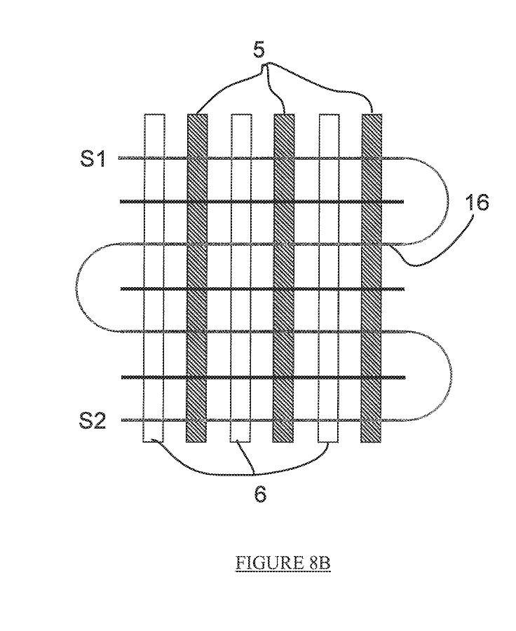

FIG. 8a represents a row of a heat exchange bundle with the thermal conduction separators electrically mounted in parallel; and

FIG. 8b represents a row of a heat exchange bundle with the thermal conduction separators electrically mounted in series.

As an example, the invention will be presented in relation to a motor vehicle heat exchanger with electrical energy generation. However, it goes without saying that this invention applies to any electrical energy generation device comprising two heat sources of different temperatures.

Conventionally, a heat exchanger 1, or cooler, for a motor vehicle is mounted in a gas cooling line of the vehicle. Referring to FIGS. 1 and 2, the heat exchanger 1 comprises a heat exchange bundle 3 comprising tubes 5 or ducts for the circulation of a fluid to be cooled, in this case hot gases of temperature T1, hereinafter designated hot gas tubes 5, and tubes 6 or ducts for the circulation of a coolant of temperature T2 lower than the temperature T1 of the hot gases, hereinafter designated cooling tubes 6. The heat exchange bundle 3 extends along an axis X, hereinafter designated X axis of the heat exchanger 1.

The hot gas tubes 5 and the cooling tubes 6 form ducts for fluids of different temperatures.

The hot gases and the coolant are introduced into the tube bundle of the heat exchanger 1 via an inlet manifold box 2 placed at the inlet of the tube bundle 3 of the heat exchanger 1. An outlet manifold box 4, of the same type as that mounted at the inlet of the heat exchanger 1, is installed at the outlet of the exchanger 1 to receive the fluids that have passed through the hot gas tubes 5 and the cooling tubes 6. The inlet manifold box 2 in this case comprises a hot gas inlet nozzle 21 and a coolant inlet nozzle 22, the outlet manifold box 4 similarly comprising two outlet nozzles respectively making it possible to evacuate the hot gases and the coolant 41, 42.

The hot gas tubes 5 and the cooling tubes 6 of the heat exchange bundle 3 are held at their ends by manifold plates (or manifolds) housed in, the inlet 2 and outlet 4 manifold boxes, the manifold plates, not represented, comprising orifices for securing the hot gas tubes 5 and the cooling tubes 6.

Referring now to FIG. 2, the hot gas tubes 5 are arranged in parallel on one or more rows (R1, R2) in the heat exchange bundle 3, these tubes 5 being intended for the circulation of hot gases which are, in this example, exhaust gases from the internal combustion heat engine of the vehicle. These exhaust gases, which have a temperature exceeding 200° C., are intended to be cooled by the heat exchanger 1 by the circulation of the coolant whose temperature is lower than that of the exhaust gases.

Referring to FIG. 2, the heat exchange bundle 3 also comprises cooling tubes 6 which are arranged between the hot gas tubes 5 for each row of tubes (R1, R2) of the heat exchange bundle 1, the cooling tubes 6 being intended for the circulation of a coolant, in this case water added to glycol whose temperature T2 is approximately 60° C.

In other words, a row of heat exchange tubes (R1, is in the form of a set of cooling tubes 6 and of hot gas tubes 5, all arranged in parallel in one and the same plane, equidistant from one another. The cooling tubes 6 are alternated with the hot gas tubes 5 in order to allow for a heat exchange from the hot exhaust gases (T1>200° C.) to the coolant (T2=60° C.). Referring to FIG. 2, the cooling tubes 6 and the hot gas tubes 5 are arranged, by way of example, in two rows (R1, R2).

In this example, the hot and cold fluids circulate in rectilinear metal tubes 5, 6 extending from one end to the other of the heat exchange bundle 3 along the axis X of the heat exchanger 1, the metal tubes 5, 6 of the heat exchange bundle 3 being made of a metal such as aluminum, copper or stainless steel. The diameter of the tubes 5, 6 may differ according to the fluids circulating therein.

In addition to its cooling function, the heat exchanger 1 has a secondary function consisting in generating electrical energy from the calorific energy of the exhaust gases from the vehicle. Such a heat exchanger 1 makes it possible to power electrical equipment items of the vehicle (headlights, air conditioning system, etc.) by limiting the fuel consumption of the vehicle and, consequently, the evacuation into the atmosphere of polluting particulates such as carbon dioxide (CO₂).

In order to generate electrical energy, the heat exchanger 1 comprises thermoelectrical elements 10, having at least two faces 10A, 10B. A thermoelectrical element 10 makes it possible to generate an electric current between its two faces 10A, 10B when they are at different temperatures. In other words, if one face 10A of the thermoelectrical element 10 is heated while its other face 10B is cooled, a displacement of electrons is created between the hot 10A and cold 10B faces of the thermoelectrical element 10, the displacement of electrons forming an electric current. The greater the temperature difference (T1−T2) between the faces 10A, 10B of the thermoelectrical element 10, the greater the electrical energy generated by the thermoelectrical element 10.

Referring to FIG. 3, a thermoelectrical element 10 is arranged between two thermal conduction separators 15, 16 which are respectively in contact with the two faces 10A, 10B of the thermoelectrical element 10.

As an example, with reference to FIGS. 3 and 4, a first thermal conduction separator 15, hereinafter designated hot separator 15, thermally links a hot gas tube 5 to a first face 10A of the thermoelectrical element 10, known as hot face 10A of the thermoelectrical element 10. Similarly, a second thermal conduction separator 16, hereinafter designated cold separator 16, thermally links a cooling tube 6 to a second face 10B of the thermoelectrical element 10, known as cold face 10B of the thermoelectrical element 10. In this case, the hot separators 15 and the cold separators 16 are passed through both by the cooling tubes 5 and by the hot gas tubes 6.

Referring to FIG. 4, representing the positioning of the thermoelectrical element 10 relative to the hot 15 and cold 16 separators, the thermoelectrical element 10 is in the form of a single parallelepiped or of a set of several independent parallelepipeds forming a square of side roughly equal to 10 mm and thickness roughly equal to 5 mm. The thermoelectrical element 10 is known per se and includes, in this example, bismuth and tellurium (Bi₂Te₃). It goes without saying that the thermoelectrical element could also include TAGS (tellurium, arsenic, germanium, silicon), PbTe (lead-tellurium) or other components assembled in parallel layers.

A thermoelectrical element 10 has a specific orientation which is determined by the arrangement of the layers of material that it comprises. Thus, as an example, for a thermoelectrical element 10 comprising a layer of Bi₂Te₃ and a layer of PbTe, the cold face 10B of the thermoelectrical element 10 corresponds to the layer of Bi₂Te₃, whereas its hot face 10A corresponds to the layer of PbTe. Thus, when a thermoelectrical element 10 is mounted between two separators 15, 16, it is essential to be careful with the orientation of the thermoelectrical element 10 so that its hot 10A and cold 10B faces are respectively in contact with the hot 15 and cold 16 separators.

The thermal conduction separators 15, 16 extend orthogonally with respect to the tubes 5, 6 of the heat exchange bundle 3 and parallel to one another, the hot separators 15 being alternated with the cold separators 16. The thermal conduction separators 15, 16, hot or cold, are in the form of rectilinear strips of a thickness roughly equal to 1 mm. The strips are metallic and may comprise aluminum, copper, stainless steel or another heat-conducting metallic material.

Each thermal conduction separator, hot 15 or cold 16, includes, in its length, orifices 151, 152, 161, 162 arranged to allow for the passage of the hot gas metal tubes 5 and the cooling metal tubes 6, each thermal conduction separator 15, 16 has two types of orifices: thermal conduction orifices 152, 162 and thermal insulation orifices 151, 161 which are alternated with the separator 15, 16 according to its length.

Referring to FIGS. 3, 4 and 5, a cooling tube 6 and a hot gas tube 5 of the heat exchange bundle 3 are linked to a thermoelectrical element 10 by two thermal conduction separators 15, 16.

Referring more particularly to FIG. 5, the hot separator 15 includes a thermal conduction orifice 152 in which the hot gas tube 5 is held in position, electrical insulation means 70 here being arranged between the external surface of the hot gas tube 5 and the internal surface of the conduction orifice 152 of the hot separator 15. In this example, the hot gas tube 5 is covered with an electrically insulating paint or varnish 70 preventing the conduction of an electric current between the hot separator 15 and the hot gas metal tube 5. Other electrical insulation means 70 could also be appropriate, such as an elastomer ring which would be arranged between the hot gas tube 5 and the conduction orifice 152 of the hot separator 15, the important thing being that the electrical insulation means 70 should not disturb the thermal conduction.

The hot separator 15 also includes a thermal insulation orifice 151 into which the cooling tube 6 is introduced, thermal and electrical insulation means 80 here being arranged between the external surface of the cooling tube 6 and the internal surface of the insulation orifice 151 of the hot separator 15. In this example, the cold tube 6 is introduced without contact with the insulation orifice 151, air 80 insulating the hot separator 15 and the cooling metal tube 6. Other thermal and electrical insulation means 80 could also be appropriate such as ceramic rings in order to avoid the conduction of the thermal and electrical energy between the hot separator 15 and the cooling tube 6, ceramic rings 80 also making it possible to ensure that the cooling tubes 6 are held in position by the hot separators 15.

Similarly, the cold separator 16 includes an insulation orifice 161 in which the hot gas tube 5 is held in position, thermal and electrical insulation means 80, similar to those described previously, also being arranged between the hot gas tube 5 and the insulation orifice 161 of the cold separator 16. Similarly, the cold separator 16 also includes a conduction orifice 162 in which the cooling tube 6 is held in position, electrical insulation means 70, similar to those described previously, also being arranged between the external surface of the cooling tube 6 and the internal surface of the conduction orifice 162 of the cold separator 16.

Referring to FIG. 3, the hot gas tube 5 is introduced successively into the securing and thermal conduction orifice 152 of the hot separator 15 and into the thermal insulation orifice 161 of the cold separator 16. Similarly, the cooling tube 6 is introduced successively into the thermal insulation orifice 151 of the hot separator 15 and into the securing and thermal conduction orifice 162 of the cold separator 16.

The securing of all the hot gas tubes 5, cooling tubes 6, hot separators 15 and cold separators 16 can be achieved, for example, by clamping by means of a tool introduced into the tubes so as to deform their walls and apply them with force against the orifices 151, 152, 161 and 162 provided, in the separators 15 and 16. This type of assembly is said to be of mechanical type. As already indicated above, the ends of the tubes terminate in manifold boxes at orifices provided in a manifold plate of said box. Depending on the mechanical assembly mode, a seal may be provided between said tubes and said plate at said orifices.

The securing of all the hot gas tubes 5, cooling tubes 6, hot separators 15 and cold separators 16 can also be achieved by mechanical inflation of the tubes 5, 6 so as to prestress them on the separators 15, 16.

For its part, the thermoelectrical element 10 is held between the hot 15 and cold 16 separators, the faces 10A, 10B of the thermoelectrical element 10 being in contact with the surface portions of the conduction separators contained between a securing and conduction orifice 152, 162 and an insulation orifice 151, 161.

After having described the structure of the means of the invention, its operation and its implementation will now be discussed.

The operation of the invention will first of all be described from an individual point of view, for a single thermoelectrical element, then for two coupled thermoelectrical elements and finally generalized to all of the heat exchange bundle of the heat exchanger.

### Electrical Energy Generation by a Single Thermoelectrical Element

Referring to FIG. 3, the hot gas conduction metal tube 5 is thermally linked to the hot separator 15 whose temperature is roughly equal to the temperature of the exhaust gases circulating in said hot gas tube 5. Similarly, the coolant conduction metal tube 6 is thermally linked to the cold separator 16 whose temperature is roughly equal to the temperature of the coolant circulating in said cooling tube 6.

The hot 10A and cold 10B faces of the thermoelectrical element 10 are respectively in surface contact with the hot 15 and cold 16 separators, a thermal gradient being formed between the faces 10A, 10B of the thermoelectrical element 10 leading to the formation of an electric current between said faces 10A, 10B by Seebeck effect. The electric current circulates in the hot 15 and cold 16 separators to then be recovered at their ends in order to be used. The recovery of the electric current will be detailed hereinbelow.

### Electrical Energy Generation by Two Coupled Thermoelectrical Elements

Although the Seebeck effect can occur for a single thermoelectrical element 10, this effect can be reinforced and the electrical energy generated can thus be increased, by coupling two thermoelectrical elements 10, thus forming a current-generating thermoelectrical junction.

A thermoelectrical junction comprises a first thermoelectrical element 10, said to be of type p, and a second thermoelectrical element 10′, said to be of type n. These two thermoelectrical elements 10, 10′ are linked in series by a conductive material whose thermoelectrical power is assumed to be zero.

As an example, referring to FIG. 6, a thermoelectrical junction is provided in a stack successively comprising a first cold separator 16, a first thermoelectrical element 10 (forming the link P), a hot separator 15, a second thermoelectrical element 10′ (forming the link N) and a second cold separator 16′. The thermoelectrical elements 10, 10′ are in this case mounted in opposite directions. The orientation of each thermoelectrical element 10, 10′ is represented by arrows in FIG. 6, the arrows pointing toward the cold face of the thermoelectrical element 10, 10′. In practice, as indicated previously, a thermoelectrical element 10, 10′ has an orientation that is determined, by the arrangement of the layers of material that it comprises. In this example, the thermoelectrical elements 10, 10′ are oriented in opposite directions in order for their hot faces 10A, 10A′ to be in contact with the hot separator 15 and for their cold faces 10B, 10B′ to be respectively in contact with the first and second cold separators 16, 16′.

Because of the Seebeck effect, an individual electric current is formed in each of the thermoelectrical elements 10, 10′. Because of the orientation of the thermoelectrical elements 10, 10′ in opposite directions, an electric current is formed with an intensity that is greater than that of an individual current deriving from a single thermoelectrical element 10 or 10′.

Thus, an electric current is formed between the first and second cold separators 16, 16′, this overall electric current being able to be recovered to power electrical equipment items.

### Electrical Energy Generation in a Row of Tubes of a Heat Exchange Bundle

Referring to FIG. 8A, in a row of tubes of a heat exchange bundle, the hot 15 and cold 16 separators are alternated to keep the metal tubes 5, 6 parallel and coplanar.

Referring to FIG. 7 representing a closer view of the row of the heat exchange bundle 3, thermoelectrical junctions are provided between two successive cold separators 16, and this between each hot gas tube 5 and each cooling tube 6.

Referring to FIG. 6, the electric currents generated by each of the three thermoelectrical junctions, arranged between the two cold separators 16, are added together to create an electrical potential difference (ΔV) of high amplitude between the cold separators 16. In other words, the greater the number of tubes and separators, the greater the quantity of electrical energy generated.

Still with reference to FIG. 8A, the cold separators 16 of one and the same row of tubes of a heat exchange bundle 3 are electrically mounted in parallel. A parallel mounting of the cold separators 16 advantageously makes it possible to recover an electric current with a high electric intensity to power electrical equipment items of the vehicle. The ends (P1, P2, P3, P4) of the cold separators 16 form electric terminals arranged to allow for the recovery of the current generated by the row of tubes of the heat exchange bundle 3.

In this embodiment, the thermoelectrical elements inserted between a hot separator and a cold separator that are adjacent are of the same type (in other words, they are all of type p or of type n). In other words, in this embodiment, between a hot tube and a cold tube that are adjacent, thermoelectric elements of different type are alternated (p then n then p then n), each thermoelectrical element being separated from its neighbor by a separator.

According to another embodiment, with reference to FIG. 8B, the cold separators 16 of one and the same row of tubes of a heat exchange bundle 3 are electrically mounted in series. In other words, for a given cold separator, its ends are respectively linked to the cold separators of its row which are closest to it, i.e. the separators mounted above and below said given cold separator as represented in FIG. 8B. A series mounting of the cold separators 16 advantageously makes it possible to recover a high electric voltage to power electrical equipment items of the vehicle. Referring to FIG. 8B, the four cold separators 16 of the heat exchange bundle 3 are in this case linked in series, a cold separator placed roughly in the middle of the row having one end connected to the cold separator placed above it and one end connected to the cold separator placed below it.

Still referring to FIG. 8B, the cold separators 16 arranged at the ends of the row of the heat exchange bundle 3 each have a free end S1, S2, which is not connected to the other cold separators 16 of the row. These free ends S1, S2 form electric terminals S1, S2 via which the electrical energy generated by the row of the heat exchange bundle 3 can be taken in order for it to be used. Hereinafter, the term “series” row of the heat exchange bundle will be used to designate hot gas tubes 5 and cooling tubes 6, which are parallel, coplanar and secured by hot and cold separators 15, 16, and whose cold separators are connected in series.

### Electrical Energy Generation in a Heat Exchange Bundle

Furthermore, in an embodiment that is not represented, a heat exchange bundle 3 comprises rows of the “series” type which are electrically linked in series with one another.

For a heat exchange bundle 3 comprising a vertical stack of several rows of the “series” type, each row includes two free terminals S1, S2 as detailed previously. For a row Rₙ of this stack, its first free terminal Sₙ1 is electrically connected to a free terminal (Sₙ₊₁1, Sₙ₊₁2) of the row Rₙ₊₁ of the stack mounted above said row Rₙ. Similarly, the second free terminal Sₙ2 of said row Rₙ is electrically connected to a free terminal (Sₙ₋₁1, Sₙ₋₁2) of the row Rₙ₋₁ of the stack mounted below said row Rₙ.

Once all the rows of the “series” type have been connected to one another, only the rows arranged at the top and bottom ends of the vertical stack have unconnected electric terminals. The electrical energy generated by the stack of rows of the “series” type of the heat exchange bundle is taken via said unconnected electric terminals.

In the preceding examples, a thermoelectrical junction has been described between two cold separators 16. It goes without saying that a thermoelectrical junction could also be created between two hot separators 15.

According to another embodiment which is not represented, each fluid circulation tube is bent and in the form of a U. According to this alternative, the hot gases are introduced into and evacuated from the heat exchanger via hot gas nozzles formed in a first manifold box arranged at a first end of the heat exchanger, the coolant being introduced into and evacuated from the exchanger via nozzles formed in a second manifold box arranged at a second end of the heat exchanger, opposite to the first end through which the hot gases circulate.

In other words, the hot gases are introduced and evacuated via one end of the heat exchange bundle whereas the cooling fluid is introduced and evacuated via the opposite end. Such a configuration of the heat exchanger advantageously makes it possible to dissociate the circulation of the hot fluids from the circulation of the cold fluids, one end of the heat exchange bundle being reserved for the circulation of the hot fluids and another for the circulation of the cold fluids.

Metal tubes have been presented in the preceding exemplary embodiments. However, it goes without saying that the tubes could be made of other materials in order to allow for a thermal conduction of the heat from the fluids circulating in the tubes.

1. A device for generating electrical energy by conversion of calorific energy into electrical energy, comprising:
a first duct for a hot fluid (5), the hot fluid having a temperature T1;
a second duct for a cold fluid (6), the cold fluid having a temperature T2 which is lower than the temperature T1 of the hot fluid; and
a thermoelectrical element (10, 10′), having at least two faces (10A, 10B), arranged to generate an electric current between its faces (10A, 10B) when they are at different temperatures,
the faces (10A, 10B) of the thermoelectrical element (10, 10′) being linked respectively to the ducts for fluids of different temperatures (5, 6) via thermal conduction means (15, 16).

2. The device as claimed in claim 1, in which the thermal conduction means (15, 16) are arranged to form, with the thermoelectrical element (10, 10′), an electric battery of which the thermal conduction means (15, 16) are the terminals.

3. The device as claimed in claim 1, in which the thermal conduction means (15, 16) are arranged to electrically insulate the fluid ducts (5, 6) of the thermoelectrical element (10, 10′).

4. The device as claimed in claim 1, in which the thermal conduction means (15, 16) are arranged to ensure that the fluid ducts (5, 6) are kept in position.

5. The device as claimed in claim 1, in which the thermal conduction means (15, 16) are in the form of a first hot thermal conduction separator (15), linked to the hot fluid duct (5), and a second cold thermal conduction separator (16), linked to the cold fluid duct (6), the hot and cold separators (15, 16) being linked to two different faces (10A, 10B) of the thermoelectrical element (10, 10′).

6. The device as claimed in claim 5, in which each separator (15, 16) includes a thermal insulation orifice (151, 161) and a thermal conduction orifice (152, 162), with each fluid duct (5, 6) passing through the two separators (15, 16).

7. A heat exchange bundle (3) of a heat exchanger (1) for a motor vehicle intended to cool a fluid to be cooled with the fluid to be cooled circulating in at least one duct, the fluid to be cooled being cooled by a coolant of a temperature lower than that of the fluid to be cooled, the coolant circulating in at least one coolant duct, the bundle (3) comprising an electrical energy generation device as claimed in claim 1, the duct for fluid to be cooled forming the hot fluid duct (5) and the coolant duct forming the cold fluid duct (6).

8. The bundle (3) as claimed in claim 7, comprising a plurality of ducts for fluid to be cooled (5) and a plurality of coolant ducts (6), in which the ducts for fluid to be cooled (5) are spatially alternated with the coolant ducts (6).

9. The bundle (3) as claimed in claim 8, in which the plurality of coolant ducts (6) is kept in position by a plurality of cold separators (16) and the plurality of ducts for fluid to be cooled (5) is kept in position by a plurality of hot separators (15), the cold separators (16) being spatially alternated with the hot separators (15).

10. The bundle (3) as claimed in claim 9, in which the coolant ducts (6) and the ducts for fluid to be cooled (5) are parallel and coplanar and form, with the hot and cold separators (15, 16), a row (R1, R2) of the bundle (3).

11. The bundle (3) as claimed in claim 9, in which thermoelectrical elements (10) are arranged between the cold separators (16) and the hot separators (15), each thermoelectrical element (10) having a face in contact with a hot separator (15) and another face in contact with a cold separator (16).

12. The bundle (3) as claimed in claim 11, in which thermoelectrical junctions are arranged between two successive cold separators (16), a thermoelectrical junction comprising two thermoelectrical elements (10, 10′) mounted in reverse directions and separated by a hot separator (15).

13. The bundle (3) as claimed in claim 8, in which the cold separators (16) are electrically connected in series with one another.

14. The bundle (3) as claimed in claim 10, in which the heat exchange bundle (3) comprises a plurality of rows (R1, R2).

15. The bundle (3) as claimed in claim 14, in which the rows (R1, R2) of the bundle (3) are electrically connected in series with one another.

16. The bundle (3) as claimed in claim 8, in which the flow of hot gas to be cooled is a flow of exhaust gas from an internal combustion engine of the motor vehicle.

17. A heat exchanger comprising a heat exchange bundle (3) as claimed in claim 8.
